(19) United States
(12) Patent Application Publication
(10) Pub. No.: US 2014/0077809 A1
(43) Pub. Date: Mar. 20, 2014

(54) METHOD AND APPARATUS FOR PRODUCING A SERIES OF IMAGE DATA SETS FOR AN EXAMINATION REGION LOCATED IN A MEASUREMENT VOLUME OF A MAGNETIC RESONANCE APPARATUS

(71) Applicant: Sebastian Schmidt, Weisendorf (DE)

(72) Inventor: Sebastian Schmidt, Weisendorf (DE)

(21) Appl. No.: 14/031,268

(22) Filed: Sep. 19, 2013

(30) Foreign Application Priority Data
Sep. 19, 2012 (DE) 102012216711.0

(51) Int. Cl. G01R 33/561

(52) U.S. Cl. CPC G01R 33/561
USPC 324/309

(57) ABSTRACT

Multiple scanning of regions of the k-space corresponding to a mapping region, containing the k-space center, takes place by a single-point imaging sequence and the less frequent scanning of the remaining k-space corresponding to the peripheries of the mapping region by means of a radial scanning, enables a creation of a series of image data sets, each of which exhibits a different contrast. It is thereby possible to depict time-resolved procedures, these being in a resolution that is shorter than the duration of the entire recording of measurement data for an image data set.

### BACKGROUND OF THE INVENTION

1. Field of the Invention

The invention concerns a method for creating a series of image data sets, a magnetic resonance apparatus, a computer program, and an electronically readable data medium.

2. Description of the Prior Art

Magnetic resonance (MR) is a known modality with which images of the interior of an examination subject can be generated. Expressed simply, the examination subject is positioned in a magnetic resonance apparatus in a strong, static, homogenous basic magnetic field, referred to as the B₀ field, having a field strength ranging from 0.2 Tesla to 7 Tesla and more, such that nuclear spins in the subject are oriented along the basic magnetic field. In order to trigger magnetic resonance, the examination subject is irradiated with high-frequency excitation pulses (RF pulses), and triggered magnetic resonance are measured signals that are (detected) as so-called k-space data. Based on the k-space data, MR images are reconstructed or spectroscopy data are established. For the spatial encoding of the measurement data, rapidly switched magnetic gradient fields are superimposed on the basic magnetic field. The acquired measurement data are digitized, and entered as complex number values in a k-space matrix. An MR image can be reconstructed from the k-space matrix populated with such values, by means, e.g. of a multi-dimensional Fourier transformation.

By acquiring MR data with very short echo times TE (e.g. TE<500 μs) new fields of application are made available in magnetic resonance tomography. As a result, it is possible to depict substances or tissues that cannot be depicted by means of conventional sequences, such as, e.g., a (T) SE sequence (“(turbo) spin echo”) or a GRE sequence (“gradient echo”), because their T2 time, namely the relaxation of the cross-magnetization, for such a substance or tissue is significantly shorter than the echo time, and thus a corresponding signal from such substances or tissues at the point in time of the recording has already decayed. With echo times in the range of the corresponding decay period it is possible, for example, to depict bones, teeth or ice in an MR image, even though the T2 period of these items is in a range of 30-80 μs.

In accordance with the prior art, sequences are known that enable a very short echo time. One example is the radial UTE sequence (“Ultrashort Echo Time”), as is described, e.g. in the article by Sonia Nielles-Vallespin, “3D radial projection technique with ultrashort echo times for sodium MRI: Clinical applications in human brain and skeletal muscle,” Magn. Res. Med. 2007; 57; Pages 74-81. With this type of sequence, the gradients are powered up after a waiting period T_delay following a non- or layer-selective excitation, and at the same time, the data acquisition is initiated. The k-space trajectory scanned in this manner runs radially outwardly from the k-space center after an excitation. For this reason, these raw data must first be transferred to a Cartesian k-space grid, e.g. by means of re-gridding, prior to the reconstruction of the image data from the raw data recorded in the k-space by means of a Fourier transformation.

Another approach for enabling short echo times is to scan the k-space by points, in that the free induction decay (FID: “Free Induction Decay”) is recorded. A method of this type is also referred to as single-point imaging, because, substantially, for each RF excitation, only one raw data point is recorded in the k-space. An example of this type of method for single-point imaging is the RASP method (“Rapid Single Point (RASP) Imaging,” 0. Heid, M. Deimling, SMR, 3^{rd} Annual Meeting, Page 684, 1995). According to the RASP method, at a fixed point in time following the RF excitation for the “echo time” TE, a raw data point is selected in the k-space, the phase of which is encoded by gradients. The gradients are modified for each raw data point, or measurement point, respectively, by means of the magnetic resonance apparatus, and thus the k-space is scanned on a point-by-point basis, as is depicted in FIGS. 1a and 1b.

Grodzki et al. describe, in “Ultrashort echo time imaging using pointwise encoding time reduction with radial acquisition (PETRA),” Magn. Reson. Med., 2012 February; 67 (2): 510-8, a method which combines the specified UTE method with a single-point imaging method, such as, e.g. a RASP method. It is not possible, however, to map dynamic procedures, such as, e.g., a contrasting agent injection, due to a duration of the data acquisition resulting thereby. With the typical measurement period of a PETRA acquisition, lasting numerous minutes, the contrasting agent is already homogenously distributed in the body before the measurement is complete, such that, with the attempt to map a contrasting agent injection, only non-specific mixture contrasts can be obtained.

As an example, a so-called keyhole technique is described in U.S. Pat. No. 5,713,358 A, in which the k-space center is recorded repeatedly in relation to the remaining k-space that is to be mapped, wherein the same recording sequence is used in each case.

### SUMMARY OF THE INVENTION

An object of the present is to provide a method, a magnetic resonance apparatus, and an electronically readable data medium that are suited for the mapping of dynamic processes, and at the same time, enable particularly short echo times.

A method according to the invention for creating a series of image data sets for an examination region located in a measurement volume of a magnetic resonance apparatus by means of the magnetic resonance apparatus includes the following steps.

Measurement data are acquired by irradiating the mapping region with RF pulses and activating gradients in such a manner that k-space corresponding to the mapping region is scanned by a first region of k-space to be scanned being scanned along radial trajectories, and a second region of k-space to be scanned, which is not covered by the first region, and that contains the k-space center, is scanned at least twice by points, in a manner corresponding to a single point imaging sequence. The measurement data, recorded from the first region of the k-space that is to be scanned are stored, as first raw data set. The measurement data, recorded from the first scanning of the second region of the k-space that is to be scanned are stored, as a first additional raw data set. The measurement data, recorded from each further scanning of the second region of the k-space that is to be scanned are stored, as further additional raw data sets. An image data set is reconstructed from the first raw data set and the first additional raw data set and, in each case, one additional imaging data set from the first raw data set and a further additional raw data set.

By means of the multiple scanning according to the invention of the region of k-space corresponding to the mapping region, which contains the k-space center, by means of a single point imaging sequence and the less frequent scanning of the remaining, peripheries of the k-space corresponding to the mapping region, by means of a radial scanning, it is possible to create a series of image data sets, each of which exhibits a different contrast. In this manner, it is possible to depict time-resolved processes, said processes being depicted in a resolution that is shorter than the duration of the entire recording of measurement data for an image data set.

A magnetic resonance apparatus according to the invention, for acquiring measurement data in an examination region within an examination subject, and creation of a series of image data sets, has a basic field magnet, a gradient field system, at least one RF antenna, and a control device for controlling the gradient field system and the at least one RF antenna, for receiving the measurement data recorded by the at least one RF antenna and for evaluating the measurement data and for creating image data sets. The magnetic resonance apparatus is designed such that the magnetic resonance apparatus generates measurement data by means of the control device of this type through the irradiation of the mapping region with RF pulses and switching of gradients such that a first region of the k-space that is to be scanned is scanned along radial trajectories, and a second region, corresponding to the k-space that is to be scanned, which is not covered by the first region, and contains the k-space center, is scanned at least twice by points, in a manner corresponding to a single point imaging sequence, and the measurement data recorded from the first region of the k-space that is to be scanned are stored as the first raw data set. The measurement data recorded from the first scanning of the second region of the k-space that is to be scanned are stored as the first additional raw data set, and the measurement data recorded from each further scanning of the second region of the k-space that is to be scanned are each stored as further additional raw data sets. The magnetic resonance apparatus is furthermore designed so as to reconstruct an image data set, by means of the control device, from the first raw data set and the first additional raw data set and, in each case, an additional image data set from the first raw data set and a further additional raw data set. In particular, the magnetic resonance apparatus is designed to execute the method according to the invention, described herein.

An electronically readable data medium according to the invention is encoded with electronically readable control commands/programming instructions that cause the method according to the invention to be executed when the data medium is run in a control device of a magnetic resonance apparatus.

The advantages and designs listed in reference to the method apply analogously to the magnetic resonance apparatus, and the electronically readable data medium.

### BRIEF DESCRIPTION OF THE DRAWINGS

FIG. 1 schematically illustrates a magnetic resonance apparatus according to the invention.

FIG. 2 is a flowchart of a method according to the invention.

FIG. 3 schematically illustrates a PETRA sequence for acquiring measurement data.

FIG. 4 illustrates a PETRA sequence, modified according to the invention.

### DESCRIPTION OF THE PREFERRED EMBODIMENTS

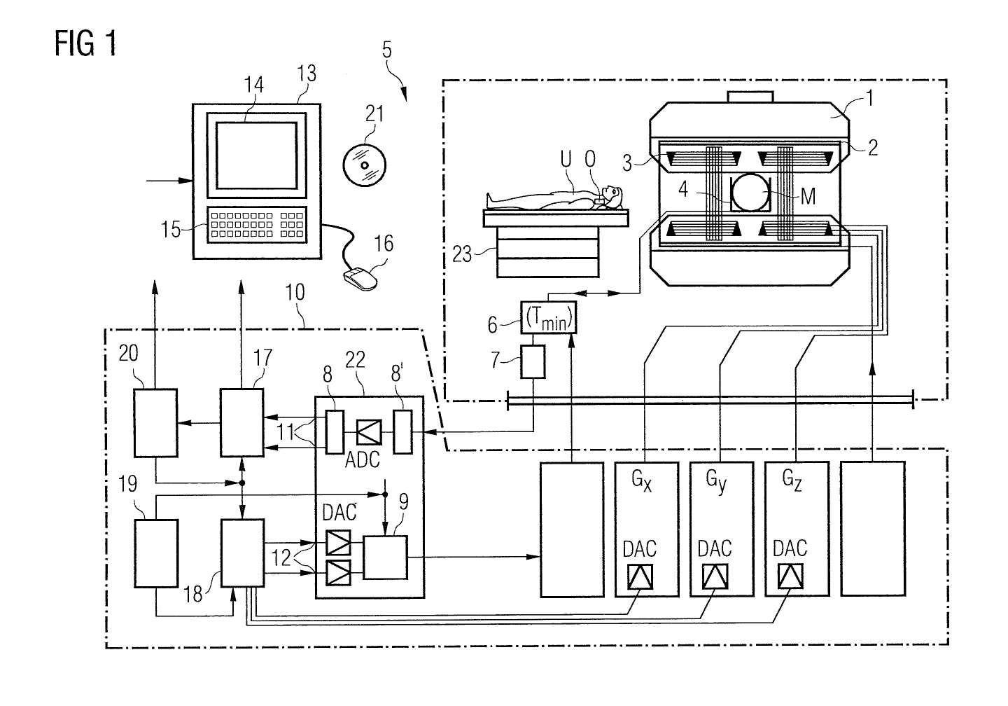

FIG. 1 schematically depicts of a magnetic resonance apparatus 5 (a magnetic resonance imaging scanner or tomography device). By this means, a basic field magnet 1 generates a magnetic field that has a temporally constant strength, for polarization or orientation of the nuclear spins in an examination region O of an examination subject U, such as, e.g. a part of a human body that is to be examined, which is examined lying on a table 23 in the magnetic resonance apparatus 5. The high degree of homogeneity of the basic field magnet, necessary for measuring the nuclear spin resonance, is defined, typically, but not necessarily, in a spherical measurement volume M, in which the part of the human body that is to be examined is located. To support the homogeneity requirements, and in particular, to eliminate effects that do not vary over time, so-called shim plates made of ferromagnetic materials are placed at appropriate locations. Effects varying over time are eliminated by means of shim coils 2.

A cylindrical gradient coil system 3 is used in the basic field magnets 1, composed of three partial windings. Each partial winding is supplied with current by an amplifier for generating an, e.g., linear (made of temporally variable) gradient field in the respective direction of the Cartesian coordinate system. The first partial winding of the gradient field system 3 generates a gradient Gₓ in the x-axis, the second partial winding generates a gradient G_{y} in the y-axis, and the third partial winding generates a gradient G_{z} in the z-axis. Each amplifier has a digital-analog converter, which is controlled by a sequencing controller 18 in order to generate gradient pulses at the correct time.

One (or more) radio-frequency (RF) antennas 4 are located within the gradient field system 3, in particular, at least one multi-channel RF transmitting coil and at least one RF receiving coil, which convert the high frequency pulses delivered by a high frequency power amplifier to a magnetic alternating field for exciting the nuclei and orienting the nuclear spins of the examination subject U that is to be examined, or the mapping region O of the examination subject U that is to be examined. Each high frequency antenna 4 consists of one or more RF transmitting coils and one or more RF receiver coils in the form of an annular, preferably linear or matrix shaped configuration of component coils, and has both a receiving mode and a transmitting mode. From the RF receiving coils of the respective high frequency antenna 4, the alternating field, i.e., normally the spin echo signal caused by a pulse sequence comprising one or more high frequency pulses and one or more gradient pulses, is converted to a voltage (measurement signal), which is sent to a high frequency receiving channel 8 of a high frequency system 22 via of an amplifier 7. The high frequency system 22, additionally, has a transmitting channel 9, in which the high frequency pulses for the excitation of the magnetic nuclear resonance are generated. For this purpose, the respective RF pulses are provided digitally as a series of complex numbers, based on a pulse sequence provided by the apparatus computer 20 in the sequence control unit 18. This number series is supplied, in the form of real and imaginary components, to a digital-analog converter in the high frequency system 22, in each case via an input 12, and from there to a transmitting channel 9. The pulse sequences of an RF carrier signal are modulated in the transmitting channel 9, the base frequency of which corresponds to the mid-band frequency.

The toggling between transmitting and receiving mode occurs via a diplexer 6, which requires a minimal switching period Tmin to switch from the transmission mode to the receiving mode. The RF transmission coils of the high frequency antenna(s) 4 emit the high frequency pulses for exciting the nuclear spins in the measurement volume M, and the resulting echo signals are scanned via the RF receiving coil(s). The accordingly acquired magnetic resonance signals are demodulated in the receiving channel 8′ (first demodulator) of the high frequency system 22 to an intermediate frequency, in a phase sensitive manner, and digitalized in the analog-digital converter (ADC). This signal is then demodulated to the frequency 0. The demodulation to the frequency 0 and the separation into real and imaginary components occurs after the digitalization in the digital domain in a second demodulator 8. By means of an imaging computer 17, an MR image, or a three-dimensional image data set can be reconstructed from the measurement data acquired in this manner. The management of the measurement data, the image data and the control program occurs via the apparatus computer 20. Based on a specification with control programs, the sequence control unit 18 controls the generation of the respective desired pulse sequences, and the corresponding scanning of the k-space. In particular, the sequence control unit 18 controls the switching of the gradients at the correct time, the transmission of the RF pulses with a defined phase amplitude, and the reception of the magnetic resonance signals.

The time base for the high frequency system 22 and the sequence control unit 18 is provided by a synthesizer 19. The selection of appropriate control programs for generating a recording of measurement data, which, e.g. are stored on a DVD 21, the selection of a selected region O, which is to be excited and received from the measurement data, the specification of a substance, with which the selected region O is filled for determining the tilt angle for the desired signal course, and the depiction of a generated MR image, occurs, e.g. via a terminal 13, which includes a keyboard 15, a mouse 16 and a display monitor 14.

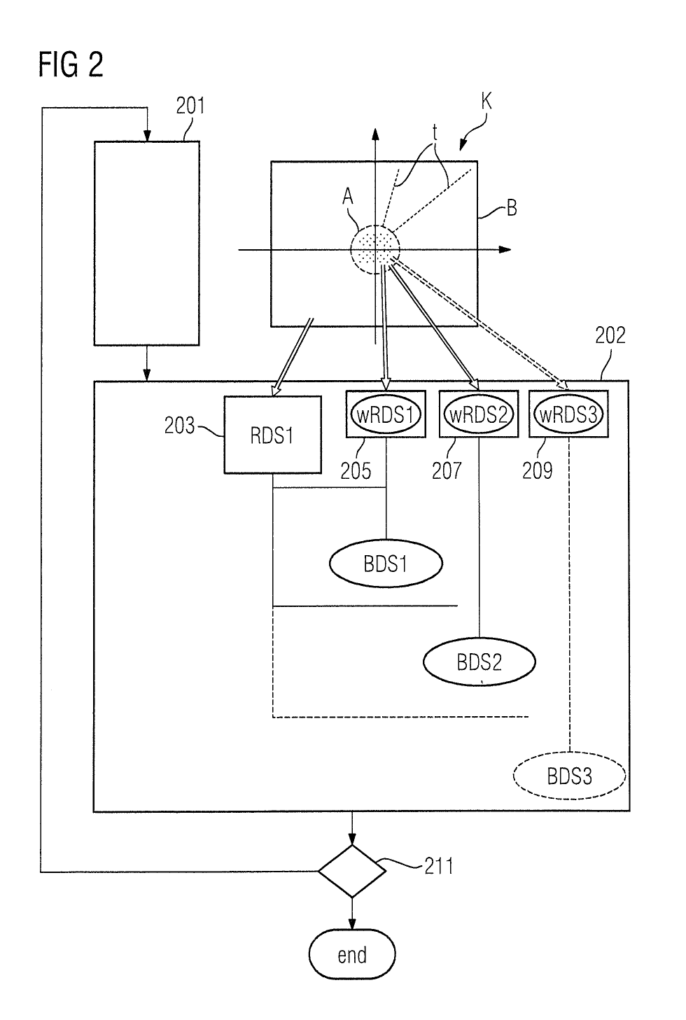

FIG. 2 show a schematic depiction of a flow diagram for a method according to the invention for creating a series of image data sets BDS1, BDS2, BDS3.

By means of the magnetic resonance apparatus, measurement data are generated and recorded in an examination region of an examination subject, in that the mapping region is irradiated with RF pulses and the gradients are switched (block 201).

This occurs in such a manner that the k-space, K=B+A, corresponding to the mapping region, schematically depicted in the upper right, is scanned such that a first region B, of k-space K to be scanned, is scanned along radial trajectories t. For clarity, only two trajectories t, as an example, are shown, schematically depicted as dotted lines 6. Moreover, the measurement data are generated and recorded such that a second region A, corresponding to the k-space K that is to be scanned, which is not covered by the first region B (A=K−B), and that contains the k-space center, is scanned at least twice by points, in a manner corresponding to a single-point imaging sequence. This is depicted in FIG. 2 by the schematic points within the region A. The arrangement of the points in region A in FIG. 2 is selected on an arbitrary basis, and can depend on the single-point imaging sequence being used. By way of example, a RASP sequence may be used for this.

A sequence corresponding to a radial portion of a PETRA sequence may be used for the radial scanning of the first region B, in particular, by means of which, on the whole, only one PETRA sequence need be used, because with this as well, a region comprising the k-space center is scanned by means of a single-point imaging sequence, such as a RASP sequence.

The echo times (TE) used can be selected such that they are different for the sequences used for the first region B and the second region A, e.g. depending on the desired contrasts, wherein one wants to make use of the effect such that the k-space center substantially determines the contrast impression, or also depending on technical requirements, which are, e.g. specified by the measurement system.

The first region B of k-space K that is to be scanned is limited to as far as the k-space center. This is indicated by the circle, depicted by a broken line, surrounding the k-space center. The extent to which the first region B can extend toward the k-space center depends on a minimal switching period (Tmin) between a transmission mode and a receiving mode of the RF antennas that are used for irradiating RF pulses and for recording measurement data. The same relationships apply as those described in the previously cited article by Godzki et al.

The measurement data recorded in this manner are processed to form a series of at least two image data sets (block 202).

The measurement data recorded from the first region B are stored as a first raw data set RDS1 (block 203).

The measurement data recorded from the first scanning of the second region A are stored as the first additional raw data set wRDS1 (block 205).

The measurement data recorded from the second scanning of the second region A are stored as the second additional raw data set wRDS2 (block 207).

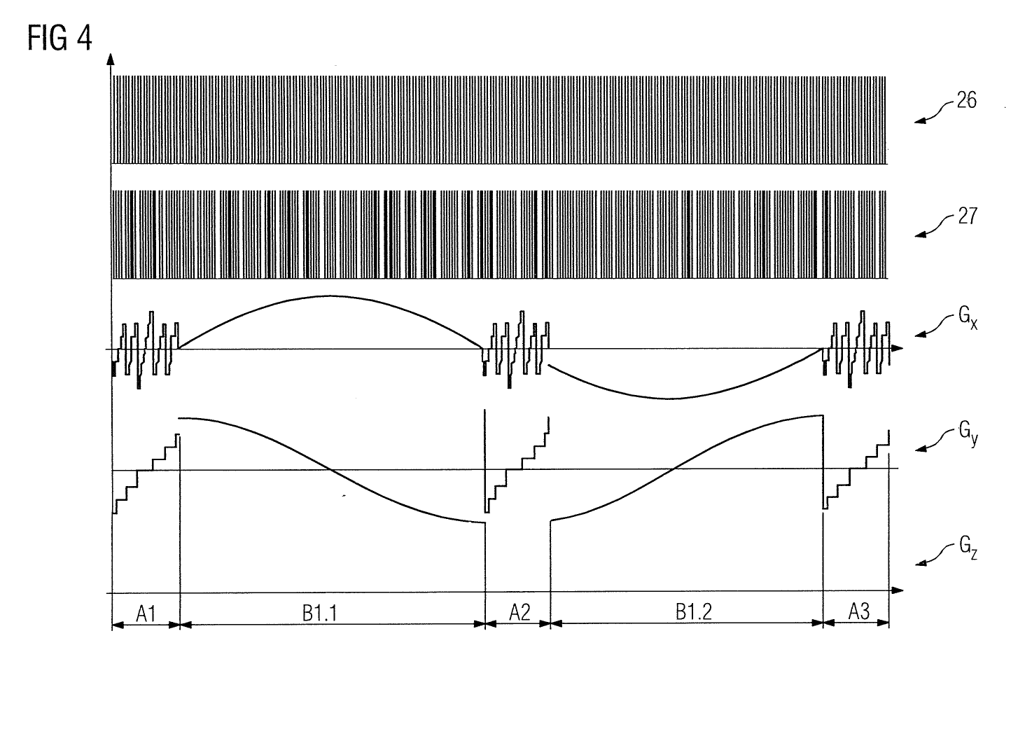

A third scanning of the second region A is also depicted in the illustrated example, wherein the measurement data obtained by means of this third scanning are stored as the third additional raw data set wRDS3 (block 209). Measurement data from further scannings of the second region A are stored analogously. In this manner, the measurement data from each additional scanning of the second region A are each stored as further additional raw data sets. Further explanation regarding the sequence in which the scannings of the first region B and the second region A occur shall be provided later in reference to FIG. 4.

The image data sets can then be reconstructed from the raw data sets RDS1, wRDS1, wRDS2, etc. obtained in this manner. For this, a first image data set BDS1, for example, is reconstructed from first raw data set RDS1, which is recorded from the peripheral region B of k-space, and the first additional raw data set wRDS1, which is recorded from the central region A of k-space.

A second image data set BDS2 can be reconstructed from the first raw data set RDS1, which is recorded from the peripheral region B of k-space, and the second additional raw data set wRDS2, which is recorded from the central region A of k-space.

If further additional raw data sets are created, then additional raw data sets can also be reconstructed. For example, a third image data set BDS3 can be reconstructed from the first raw data set RDS1, which is recorded from the peripheral region B of k-space, and the third additional raw data set wRDS3, which is recorded from the central region A of k-space. By means of the combination of the first raw data set with an additional raw data set, the image data set, in each case, is reconstructed from raw data from the entirety of k-space corresponding to the mapping region.

The contrasts in the individual image data sets BDS1, BDS2, BDS3 correspond in each case to the prevailing contrasts at the time periods in which the measurement data are recorded from the additional raw data sets that are used for the central region.

If desired, the first region B can also be scanned numerous times, but the second region A is always scanned more times, in each case, that the first region B. In this case, for example, a query 211 can question whether another scanning of the first region B is desired, and if so, restart the process at block 201. If not, the process is completed (“end”).

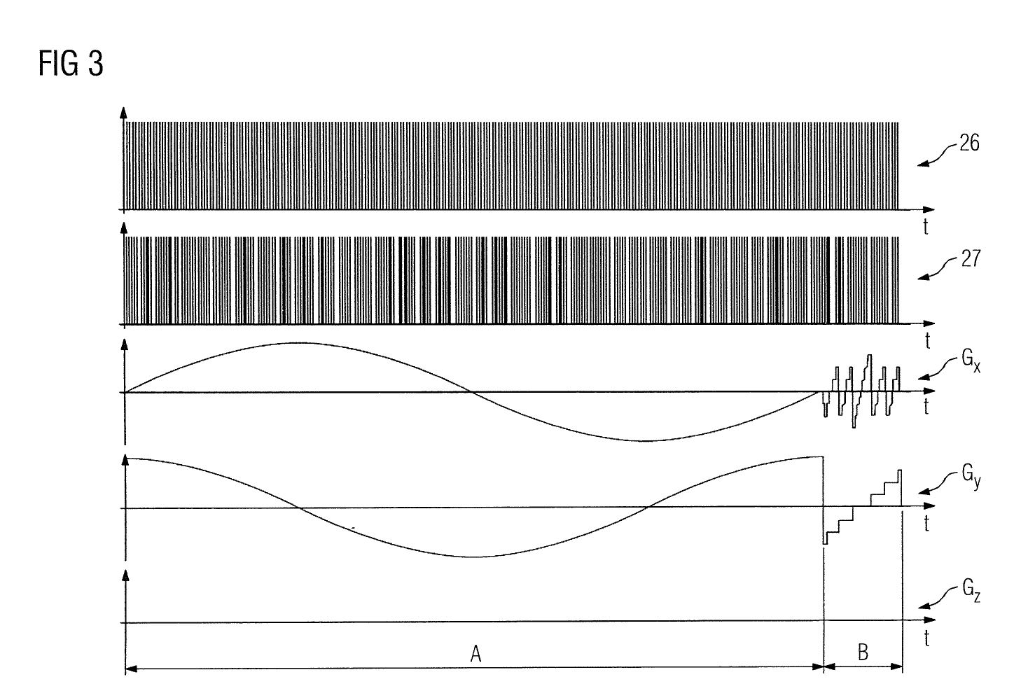

A PETRA sequence for acquiring measurement data is depicted schematically in FIG. 3. For purposes of clarity, one PETRA sequence diagram is selected for acquiring projection data.

The first line in FIG. 3 shows the irradiated RF excitation pulses 26, the second line shows the associated readout time periods 27.

Only two phase encoding gradients are toggled here. An encoding in the third axis, the direction of the layer, in this case the z-axis, is not carried out (G_{z}=0). With recordings of three-dimensional measurement data sets, the process shown must be repeated for each gradient in the third axis, resulting in longer measurement periods. This means the scanning of region B would be increased by a factor of m for scanning m gradient trajectories in the axis of the layers.

The phase encoding gradients in the x and y axes are Gₓ=sin(φ) or G_{y}=cos(φ), respectively, wherein φ, starting at φ=0, for example, is increased for each radial k-space trajectory by an angle of 360°/(number of projections N_{Proj}), until 360° have been obtained. Thus, for the projection data set, a total of N_{Proj} radial projections, i.e. N_{Proj} radial k-space trajectories, are recorded. This is illustrated in FIG. 2 in the region “A,” wherein 250 radial k-space trajectories are selected, which scan a first region of the k-space that is to be scanned.

The readout of Cartesian k-space points in a second region, which corresponds to the k-space that is to be scanned that is not covered by the first region and contains the k-space center, by means of a single-point imaging process, is depicted in region “B” in FIG. 3.

FIG. 4 shows a PETRA sequence from FIG. 3, modified according to the invention. The depiction as a projection sequence is again maintained for purposes of clarity. With a three-dimensional recording of measurement data the entire region B is increased (here, B=B1.1+B1.2), as described in reference to FIG. 3.

In the embodiment example shown in FIG. 4, first the second region, comprising the k-space center, is scanned (A1) a first time, after which the scanning of the second region is begun (B1.1). In the illustrated case, the scanning of the second region (B=B1.1+B1.2) is interrupted once in order to scan the first region a second time (A2). After the first region has been fully scanned (end of B1.2), the second region is scanned yet a third time (A3). In this manner, the second region A (A=A1=A2=A3) is scanned at three different time periods. In the depicted example, the time periods in which the second region A is scanned are evenly distributed about the scanning of the first region B=B1.1+B1.2.

In other embodiments, the first region B can, for example, be scanned without interruption, and the second region A can be scanned, for example, prior to and following the scanning of the first region B (scanning: ABA). Likewise, it is also possible to scan the second region A numerous times before the first region B is scanned (scanning: AA . . . B). In the same manner, it is also possible to scan the second region A numerous times after the first region B has been scanned (scanning: BAA . . . ). And interruption, or numerous interruptions of the scanning of the first region B at arbitrary points in time, in order to scan the second region A once, or numerous times, is also possible.

The alternating of the scanning of the first region B and the second region A, wherein A is always fully scanned in a contiguous manner, can thus be designed in a variable manner, wherein arbitrary combinations of the possibilities specified above can also be implemented. The point at which a scanning of the second region A occurs can be selected, in particular, such that the time periods for the different scannings of the second region A occur such that the expected differences in contrast over the course of the entire recording are reproduced well in the image data sets reconstructed from the corresponding raw data sets.

In accordance with the embodiment example depicted in FIG. 4, a first image data set BDS1 can now be reconstructed from the raw data sets acquired from the first region B=B1.1+B1.2, and the first scanning of the second region A1. The contrast in this first image data set BDS1 is determined by the first additional raw data set, at the point in time of the first scanning of the second region (A1).

A second image data set BDS2 can be reconstructed from the raw data sets acquired from the first region B=B1.1+B1.2 and the second scanning of the second region A2. The contrast in this second image data set BDS2 is determined by the second additional raw data set thereby, at the point in time of the second scanning of the second region (A2).

A third image data set BDS3 can be reconstructed from the raw data sets acquired from the first region B=B1.1+B1.2 and the third scanning of the second region A3. The contrast of in this third image data set BDS3 is determined by the third additional raw data set, at the point in time of the third scanning of the second region (A3).

In this manner, a series of image data sets BDS1, BDS2, BDS3 is obtained, the contrasts of which change in accordance with the prevailing conditions during the recording of the respective raw data from the second region (A1, A2, A3) used for the reconstruction of the image data set. In this manner, image data sets BDS1, BDS2, BDS3 are thus created that depict a contrasting that changes over time. By this means, it is possible to depict time-resolved procedures such as, for example, a rapid accumulation of contrasting agent.

Although modifications and changes may be suggested by those skilled in the art, it is the intention of the inventor to embody within the patent warranted hereon all changes and modifications as reasonably and properly come within the scope of his contribution to the art.

I claim as my invention:

1. A method to generate a series of magnetic resonance image data sets of an examination region of a subject, comprising:
operating a magnetic resonance data acquisition unit, with an examination subject located in a measurement volume of the data acquisition unit, to acquire magnetic resonance data from an examination region of the subject by irradiating the examination region with radio-frequency pulses and activating magnetic field gradients in a sequence in order to enter said magnetic resonance data into k-space organized in an electronic memory corresponding to said examination region;
operating said magnetic resonance data acquisition unit with said sequence to cause a first region of k-space to be scanned along radial trajectories and to cause a second region of k-space, not covered by said first region and that contains a center of k-space, to be scanned at least twice by points, corresponding to a single point imaging sequence;
storing the measurement data in said first region of k-space in said memory as a first raw data set;
storing the magnetic resonance data from a first scanning of said second region as a first additional raw data set in said memory;
storing said magnetic resonance data acquired from each additional scanning of said second region as a further additional raw data set; and
in a computerized processor, accessing said memory and reconstructing an image data set from said first raw data set and said first additional raw data set and at least one additional image data set from said first raw data set and one of said further additional raw data sets, and making said image data set and said at least one additional image data set available in electronic form, as respective data files, at an output of said processor.

2. A method as claimed in claim 1 comprising scanning said first region of k-space along said radial trajectories corresponding to a radial portion of a PETRA sequence.

3. A method as claimed in claim 1 comprising limiting said first region of k-space by a minimal switching time between a transmission mode and a receiving mode of an RF antenna of said data acquisition unit that emits said RF pulses, and limiting entering data into said first region with respect to said center of k-space.

4. A method as claimed in claim 1 comprising entering said magnetic resonance data in said first region without interruption.

5. A method as claimed in claim 1 comprising entering said magnetic resonance data into said first region with at least one interruption during which said magnetic resonance data are entered into said second region.

6. A method as claimed in claim 1 comprising entering said magnetic resonance data into said second region prior to entering said magnetic resonance data into said first region.

7. A method as claimed in claim 1 comprising entering said magnetic resonance data into said second region after completely scanning said first region.

8. A method as claimed in claim 1 comprising scanning said first region multiple times and scanning said second region more times than said first region.

9. A magnetic resonance apparatus comprising:
a magnetic resonance data acquisition unit comprising a measurement volume, and an RF transmission/reception arrangement and a gradient coil arrangement;
a control unit configured to operate the magnetic resonance data acquisition unit, with an examination subject located in said measurement volume, to acquire magnetic resonance data from an examination region of the subject of the subject by irradiating the examination region with radio-frequency pulses and activating magnetic field gradients in a sequence in order to enter said magnetic resonance data into k-space organized in an electronic memory corresponding to said examination region;
said control unit being configured to operate said magnetic resonance data acquisition unit with said sequence to cause a first region of k-space to be scanned along radial trajectories and to cause a second region of k-space, not covered by said first region and that contains a center of k-space, to be scanned at least twice by points, corresponding to a single point imaging sequence;
said control unit being configured to store the measurement data in said first region of k-space as a first raw data set;
said control unit being configured to store the magnetic resonance data from a first scanning of said second region as a first additional raw data set;
said control unit being configured to store said magnetic resonance data acquired from each additional scanning of said second region as a further additional raw data set; and
a computerized processor configured to access said memory and to reconstruct an image data set from said first raw data set and said first additional raw data set and at least one additional image data set from said first raw data set and one of said further additional raw data sets, and to make said image data set and said at least one additional image data set available in electronic form, as respective data files, at an output of said processor.

10. A non-transitory, computer-readable data storage medium encoded with programming instructions, said storage medium being loaded into a computerized control and image reconstruction system of a magnetic resonance apparatus, said magnetic resonance apparatus comprising a magnetic resonance data acquisition unit comprising an RF transmission/reception arrangement and a gradient coil arrangement, and said programming instructions causing said control and image reconstruction system to:
operate a magnetic resonance data acquisition unit, with an examination subject located in a measurement volume of the data acquisition unit, to acquire magnetic resonance data from an examination region of the subject by irradiating the examination region with radio-frequency pulses and activating magnetic field gradients in a sequence in order to enter said magnetic resonance data into k-space organized in an electronic memory corresponding to said examination region;
operate said magnetic resonance data acquisition unit with said sequence to cause a first region of k-space to be scanned along radial trajectories and to cause a second region of k-space, not covered by said first region and that contains a center of k-space, to be scanned at least twice by points, corresponding to a single point imaging sequence;
store the measurement data in said first region of k-space as a first raw data set in said memory;
store the magnetic resonance data from a first scanning of said second region as a first additional raw data set in said memory;
store said magnetic resonance data acquired from each additional scanning of said second region as a further additional raw data set in said memory; and
reconstruct an image data set from said first raw data set and said first additional raw data set and at least one additional image data set from said first raw data set and one of said further additional raw data sets, and make said image data set and said at least one additional image data set available in electronic form, as respective data files, at an output of said processor.
